(19) United States
(12) Patent Application Publication
(10) Pub. No.: US 2022/0205086 A1
(43) Pub. Date: Jun. 30, 2022

(54) METHOD FOR DEPOSITING A SEMICONDUCTOR LAYER SYSTEM, WHICH CONTAINS GALLIUM AND INDIUM

(71) Applicant: AIXTRON SE, Herzogenrath (DE)

(72) Inventor: Adam BOYD, Neu Moresnet, Kelmis (BE)

(21) Appl. No.: 17/594,996

(22) PCT Filed: May 5, 2020
(86) PCT No.: PCT/EP2020/062356

§ 371 Date: Nov. 4, 2021

(30) Foreign Application Priority Data
May 6, 2019 (DE) 10 2019 111 598.1

(51) Int. Cl. C23C 16/44; H01L 21/02; C23C 16/30; C23C 16/46; C23C 16/455; H01L 29/66

(52) U.S. Cl. CPC C23C 16/4401; H01L 21/0254; H01L 21/0262; H01L 29/66462; C23C 16/303; C23C 16/46; C23C 16/45572; H01L 21/02458

(57) ABSTRACT

In a method for depositing semiconductor layers, a first process step is performed to deposit a layer containing gallium and a second process step is performed to deposit a layer containing indium. To prevent gallium from being incorporated from residues in the process chamber into the layer containing indium when the layer containing indium is deposited, a reactive gas containing indium is additionally supplied to the process chamber during the first process step and the first process parameters are adjusted such that the first layer contains no indium, or in an intermediate step between the first and second process steps, a reactive gas containing indium is supplied to the process chamber and the process parameters are adjusted such that no indium is deposited on the substrate during the intermediate step. In the second process step, the second process parameters are adjusted such that the second layer contains no gallium.

### RELATED APPLICATIONS

This application is a National Stage under 35 USC 371 of and claims priority to International Application No. PCT/EP2020/062356, filed 5 May 2020, which claims the priority benefit of DE Application No. 10 2019 111 598.1, filed 6 May 2019.

### FIELD OF THE INVENTION

The invention relates to a method for depositing a semiconductor layer system on a substrate by feeding of reactive gases together with a carrier gas into a process chamber of a CVD reactor, wherein in a first process step with first process parameters a first gallium-containing layer or layer sequence is deposited by feeding in at least one gallium-containing first reactive gas and subsequently in a second process step with second process parameters a second, indium-containing layer or layer sequence is deposited by feeding in at least one indium-containing second reactive gas.

### BACKGROUND

With a method of such kind, which is carried out in particular in a MOCVD reactor, semiconductor multilayer structures are produced, in particular for the production of HEMTs. A silicon-doped AlN layer is first deposited on a substrate, in particular a silicon substrate. An AlGaN layer is then deposited over this. The AlGaN layer also includes an AlN layer. The layer sequence contains further AlGaN layers and a GaN layer that forms a u-GaN channel. An indium-containing layer or layer sequence is then deposited on this gallium-containing layer or layer sequence, optionally with an intermediate layer of AlN being deposited between them, wherein this layer may contain AlInN.

During the deposition of the first, gallium-containing layer sequence, parasitic deposits containing gallium form on walls of the process chamber and in particular on the process chamber ceiling, which is opposite a process chamber floor that supports the substrates. In the later, second process step, this gallium may adversely affect the layer quality of the indium-containing second layer or layer sequence due to the fact that gallium is incorporated in the indium-containing layer.

### SUMMARY OF THE INVENTION

The objective underlying the invention is to suggest measures by which the undesirable incorporation of gallium atoms in the second layer or layer sequence is suppressed.

The objective is solved by the invention described in the claims, the subclaims not only representing advantageous further developments of the invention specified in claim 1, but also stand-alone solutions to the objective.

Firstly and essentially for the invention, it is suggested that in the first process step a reactive gas containing indium atoms is fed into the process chamber in addition to the reactive gas containing gallium atoms. Trimethylindium for example, or also triethylindium may be fed into the process chamber simultaneously with, for example, trimethylgallium. However, the first process parameters are set in such a way that no indium is incorporated in the gallium-containing layer in the first process step. For this purpose, it is suggested in particular that the surface temperature of the substrates be greater than 1000° C. during the first process step. It is also suggested to use hydrogen as the carrier gas, the use of which does not favor and in fact even suppresses the deposition of indium in the layer to be deposited. Alternatively, after the first process step an intermediate step can be carried out in which an indium-containing reactive gas, for example TMI or TEI, is fed into the process chamber. Here too, H₂ is preferably used as the carrier gas. The temperature is preferably above 1000° C. The process parameters are chosen such that no indium is deposited on the substrate. An exchange reaction takes place on the process chamber ceiling, which has in particular cooled to temperatures around 100° C. during the first process step and/or the intermediate step. The indium-containing reactive gas, that is to say in particular the organometallic indium compound, reacts with gallium, which adheres to the process chamber ceiling or another wall of the process chamber. This may be elemental gallium or a gallium compound that has condensed on the process chamber ceiling. In the course of the reaction, the indium compound reacts with the gallium, wherein the organometallic indium compound is able in particular to react with the elemental gallium to form elemental indium and a volatile organometallic gallium compound. Elemental indium may remain on the process chamber ceiling. The exchange reaction may also result in an indium compound that adheres to the process chamber wall, at least temporarily. But in a variant of the method, the process chamber ceiling may also be brought to a temperature above 100° C., by lowering the gas inlet element for example, and/or by lowering a protective plate made of quartz or graphite underneath the gas inlet element, so that its surface temperature rises due to its greater proximity to the heated susceptor and its greater distance from the cooled gas inlet element. Under these conditions, an intermediate step is then carried out in which the gas outlet surface of the gas inlet element or a protective plate is closer to the heated susceptor than in the first process step. In this intermediate step, the indium-containing reactive gas is fed into the process chamber, in particular together with a carrier gas, for example hydrogen. After the intermediate step, an indium-containing layer or layer sequence is deposited on the first, gallium-containing layer or layer sequence. This takes place preferably at temperatures below 1000° C., and preferably with nitrogen as the carrier gas. During the first process step or the intermediate step, preferably as many indium atoms are fed into the process chamber as there are gallium atoms on the process chamber ceiling. For this purpose, it is suggested in particular that at process chamber ceiling temperatures lower than 100° C. the molar ratio of indium to gallium is at least one third. At higher process chamber ceiling temperatures, the molar ratio can be lower, and may be at least one tenth, for example. With the method according to the invention, the parasitic deposition of gallium on walls of the process chamber is reduced during the deposition of a gallium-containing layer, for example a gallium nitride layer or an aluminum-gallium nitride layer. It may also be provided that the simultaneous feeding in of trimethylindium or triethylindium removes a pre-existing parasitic coating containing gallium or replaces it with an indium-containing layer. In this context, the total pressures may be below 100 mbar or below 200 mbar. During the second process step, which takes place at lower temperatures, an indium-containing layer is then deposited which does not contain gallium, however.

### BRIEF DESCRIPTION OF THE DRAWINGS

In the following text, embodiments of the invention will be explained in greater detail with reference to figures. In the drawing:

FIG. 1 is a schematic representation of a layer system that has been deposited in accordance with the inventive method,

FIG. 2 depicts an apparatus for performing the method in a first operating position and

FIG. 3 shows the device according to FIG. 2 in a second operating position.

### DETAILED DESCRIPTION

The apparatus represented in FIGS. 2 and 3 is a MOCVD reactor 1 with a reactor housing which can be evacuated. Inside the housing, there is a gas inlet element 5 in the form of a showerhead with a cooled gas outlet plate 6. For this purpose, cooling channels through which a coolant can flow are located in the gas outlet plate. A multiplicity of gas outlet openings are distributed evenly over the gas outlet plate 6, extending through the gas outlet plate 6, and a process gas fed into the gas inlet element 5 from the outside flows out of these into a process chamber 2.

In the exemplary embodiment, a protective plate 10 with flow-through openings 9 is located below the gas outlet plate 6, and in an operating position according to FIG. 2, in which the protective plate 10 is arranged immediately below the gas outlet plate 6, said plate is aligned with the gas outlet openings 7. The gas outlet plate 6 may be made from quartz or graphite. The gas inlet element 5 and the gas outlet plate 6 may be made of metal, in particular stainless steel.

The bottom of the process chamber 2 has the form of a susceptor 3, which may consist of a coated graphite body. The susceptor 3 supports one or more substrates 4, which are coated with a semiconductor layer or a semiconductor layer sequence in the process chamber 2.

The susceptor 3 may be driven to rotate about an axis of rotation. The susceptor 3 is heated from below with a heating device 8 to a process temperature, which can be measured with temperature measuring devices (not shown) on the substrates 4 and/or on the broadside surface of the susceptor 3 facing towards the process chamber 2.

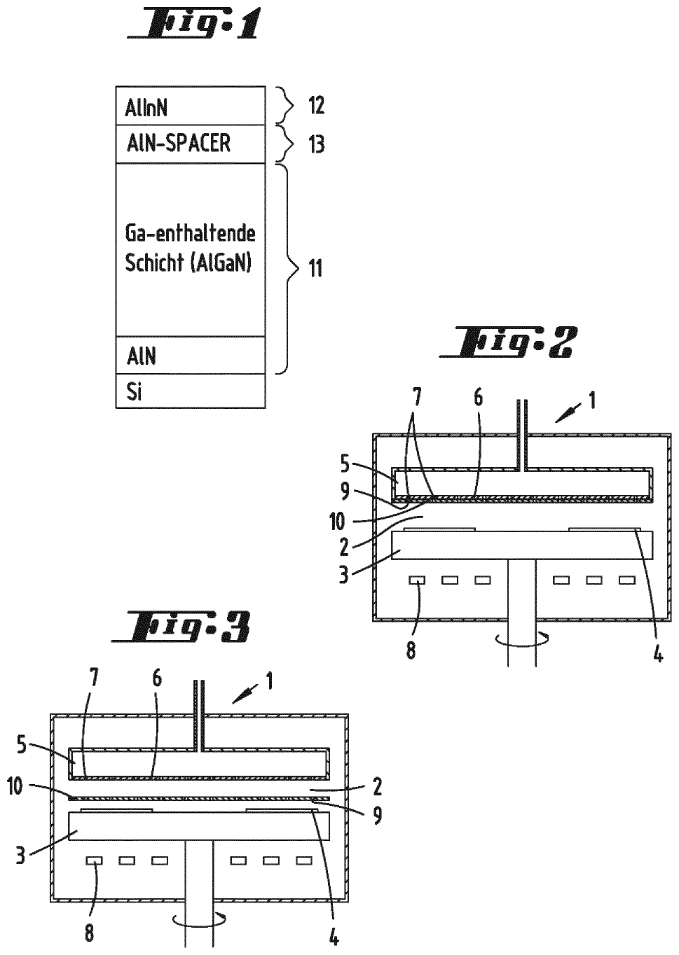

FIG. 1 shows a sequence of layers that may be deposited in the apparatus show in FIGS. 2 and 3 with the method according to the invention.

In a first phase of the coating process, a sequence of layers that may contain gallium, aluminum and nitrogen is deposited in a first process step sequence 11. This sequence of layers does not contain any indium. For this purpose, process gases in the form of ammonia and organometallic compounds of aluminum and gallium are introduced into the process chamber 2 through the gas inlet element 5. At this time, the process chamber 2 is heated to a temperature above 1000° C. During this operation, the temperature is measured on the substrate 4 and/or on the top surface of the susceptor facing towards the process chamber 2.

During the deposition of the first layer sequence 11 it is possible that gallium-containing accumulations may form on the surfaces adjoining the process chamber 2, that is to say in particular on the underside of the protective plate 10. In order to remove the accumulations of gallium or to remove the gallium in the accumulations, besides the organometallic gallium component such as TMG for example, an indium-containing reactive gas is introduced into the process chamber 2 in one of the first process steps 11 and particularly in a last of the process steps 11. This may be TMI or TEI or another organometallic indium compound. Here, the process parameters are chosen such that no indium is incorporated in the layer that is deposited in these process steps. For this purpose, the temperatures of the susceptor surface are kept above 1000° C.

On the other hand, inorganic metal compounds, for example chlorides, may also be used as reactive gases instead of organometallic compounds of gallium, aluminum and indium.

In a subsequent step, an indium-containing layer 12, 13 is deposited on the layer system. This is done by feeding a reactive indium-containing gas into the process chamber 2.

In a variant of the invention, it may be provided that the first layer sequence 11 is deposited without an indium-containing reactive gas. In an intermediate step, an indium-containing reactive gas may then be fed into the process chamber at an elevated temperature. In this case, the temperature is chosen high enough to ensure that no indium is deposited on the substrates 4. In order to raise the temperature of the surface of the protective plate 10 facing the process chamber 2, said plate may be lowered towards the heated susceptor 3, as shown in FIG. 3. During the deposition of the first layer sequence 11 and/or during the intermediate step, hydrogen is used as the carrier gas. During the subsequent deposition of the indium-containing layers, which process step is carried out at lower process temperatures, nitrogen may be used as the carrier gas.

It is provided in particular that the second layer sequence, which includes layers containing at least indium, also contains aluminum and nitrogen. For this purpose, when the second layer or layer sequence is deposited, an aluminum-containing reactive gas, in particular an organometallic aluminum compound, is also fed into the process chamber. Ammonia, which supplies the nitrogen component of the layer, is fed into the process chamber together with a carrier gas, which may be nitrogen.

The preceding notes serve to explain the inventions recorded by the application as a whole which advance the state of the art at least through the following combinations of features, each as stand-alone features as well, wherein two, several or all of said combinations of features may also be combined, namely:

A method which is characterized in that, in the first process step an indium-containing reactive gas is additionally introduced into the process chamber 2, and the first process parameters are set such that the first layer or layer sequence 11 does not contain any indium, or that, in an intermediate step between the first and the second process step, an indium-containing reactive gas is fed into the process chamber 2 and the process parameters are set such that no indium is deposited on the substrate 4 and in the second process step the second process parameters are set such that the second layer does not contain any gallium.

A method which is characterized in that the substrate temperature in the first process step or in the intermediate step is higher than 1000° C., and that the substrate temperature in the second process step is lower than 1000° C.

A method which is characterized in that the carrier gas in the first process step or in the intermediate step is H₂, and in the second process step is N₂.

A method which is characterized in that during the intermediate step the surface temperature of the process chamber ceiling is at a different and in particular a higher temperature than during the first and/or second process step, and/or that the process chamber height is reduced during the intermediate step.

A method which is characterized in that, in the first process step or in the intermediate step, the process chamber height is reduced in that a gas inlet element 5 which forms the process chamber ceiling is lowered or a protective plate 10 arranged below the gas inlet element 5 is lowered.

A method which is characterized in that the gas inlet element 5 is a showerhead with gas outlet openings 7 evenly arranged on a gas outlet surface, wherein the gas outlet surface is actively cooled.

A method which is characterized in that layers for manufacturing a HEMT are deposited on the same substrate 4, which has a diameter of at least 300 mm, during the first and the second process steps, wherein the process chamber is 9 to 25 mm high.

A method which is characterized in that the first layer or layer sequence 11 contains GaN, AlGaN or GaAs, and/or that the second layer 12 contains AlInN, and/or that an intermediate layer 13 of AlN is deposited between the first layer or layer sequence and the second layer or layer sequence.

A method which is characterized in that the temperature of the process chamber ceiling is kept at temperatures below 100° C. during the first process step or the intermediate step, wherein it is provided in particular that in the first process step the molar ratio of indium to gallium is at least ⅓, or that the process chamber ceiling temperature is greater than 100° C. and the molar ratio of indium to gallium is greater than 1/10.

All of the features disclosed (individually, but also in combination with each other) are essential to the invention. The content of the disclosure of the associated/attached priority documents (official copy of the previous application) is herewith also incorporated in its entirety in the disclosure of this application, also for the purpose of including features of said documents in claims of the present application as well. Even without the features of a referenced claim, the features of the subclaims characterize independent inventive developments of the prior art, in particular in order to make divisional applications on the basis of these claims. The invention specified in each claim may additionally have one or more of the features declared in the above description, in particular provided with reference numbers and/or specified in the list of reference numerals. The invention also relates to design forms in which some of the features mentioned in the above description are not implemented, in particular to the extent that they are manifestly dispensable for the respective purpose or can be replaced by other means with technically equivalent effect.

### LIST OF REFERENCE NUMERALS

1 CVD reactor
2 Process chamber
3 Susceptor
4 Substrate
5 Gas inlet element
6 Gas outlet plate
7 Gas outlet opening
8 Heating device
9 Gas flow-through opening
10 Protective plate
11 First layer, first layer sequence
12 Second layer, second layer sequence
13 Intermediate layer

What is claimed is:

1. A method for depositing semiconductor layers on a substrate (4) by feeding reactive gases together with a carrier gas into a process chamber (2) of a chemical vapor deposition (CVD) reactor (1), wherein during a first process step with first process parameters, a first layer (11) that contains gallium but not indium is deposited on the substrate (4) by feeding into the process chamber (2) at least one gallium-containing first reactive gas, and subsequently during a second process step with second process parameters, a second, indium-containing layer (12) is deposited on the substrate (4) by feeding into the process chamber (2) at least one indium-containing, second reactive gas, wherein:
during the first process step, an indium-containing third reactive gas is additionally fed into the process chamber (2), or during an intermediate step between the first and the second process steps, an indium-containing fourth reactive gas is fed into the process chamber (2) without depositing indium on the substrate (4), and
during the second process step, no gallium is deposited on the substrate (4).

2. The method of claim 1, wherein the first process parameters are set such that the first layer (11) contains no indium, and the second process parameters are set such that the second layer contains no gallium.

3. The method of claim 1, further comprising:
during the first process step, heating the substrate (4) to a first temperature that is high enough to ensure that no indium is deposited on the substrate (4); and
during the second process step, maintaining the substrate (4) at a second temperature that is lower than the first temperature.

4. The method of claim 1, wherein during the first process step or during the intermediate step, gallium adhering to a ceiling of the process chamber (2) or a gallium compound adhering to the ceiling of the process chamber (2) is at least partially exchanged with indium or an indium compound.

5. The method of claim 1, wherein a temperature of the substrate (4) in the first process step or in the intermediate step is higher than 1000° C., and the temperature of the substrate (4) in the second process step is lower than 1000° C.

6. The method of claim 1, wherein the carrier gas in the first process step or in the intermediate step is hydrogen gas (H₂), and the carrier gas in the second process step is nitrogen as (N₂).

7. The method of claim 1, wherein during the intermediate step, a temperature of a ceiling of the process chamber (2) is maintained at a temperature that is higher than that during one or more of the first or second process step.

8. The method of claim 1, further comprising in the first process step or in the intermediate step, reducing a height of the process chamber (2) by (i) lowering a gas inlet element (5) which forms a ceiling of the process chamber (2) or (ii) lowering a protective plate (10) arranged below the gas inlet element (5).

9. The method of claim 1, wherein the gas inlet element (5) is a showerhead with gas outlet openings (7) evenly arranged on a gas outlet surface of the gas inlet element (5), the method further comprising actively cooling the gas outlet surface.

10. The method of claim 1, wherein the semiconductor layers are part of a high electron mobility transistor (HEMT), wherein the substrate (4) has a diameter of at least 300 mm, and wherein a height of the process chamber (2) is between 9 and 25 mm.

11. The method of claim 1, wherein at least one of:
the first layer (11) contains GaN, AlGaN or GaAs,
the second layer (12) contains AlInN, or
an intermediate layer (13) of AlN is deposited between the first layer (11) and the second layer (12).

12. The method of claim 1, wherein a temperature of a ceiling of the process chamber (2) is maintained at temperatures below 100° C. during the first process step or the intermediate step.

13. (canceled)

14. The method of claim 1, further comprising reducing a height of a ceiling of the process chamber (2) during the intermediate step.

15. The method of claim 1, wherein during the first process step, a temperature of a ceiling of process chamber (2) is lower than 100° C. and the at least one gallium-containing first reactive gas contains a molar ratio of indium to gallium of at least ⅓.

16. The method of claim 1, wherein during the first process step, a temperature of a ceiling of process chamber (2) is greater than 100° C. and the at least one gallium-containing first reactive gas contains a molar ratio of indium to gallium of greater than 1/10.
